(19) United States
(12) Patent Application Publication
(10) Pub. No.: US 2017/0025183 A1
(43) Pub. Date: Jan. 26, 2017

(54) SEMICONDUCTOR MEMORY DEVICE AND OPERATING METHOD THEREOF

(71) Applicant: SK hynix Inc., Gyeonggi-do (KR)

(72) Inventor: Hee Youl LEE, Gyeonggi-do (KR)

(21) Appl. No.: 14/993,651

(22) Filed: Jan. 12, 2016

(30) Foreign Application Priority Data
Jul. 22, 2015 (KR) 10-2015-0103763

(51) Int. Cl. G11C 16/34; G11C 16/10

(52) U.S. Cl. CPC G11C 16/3459; G11C 16/10

(57) ABSTRACT

A semiconductor memory device may include a memory cell array including a plurality of memory cells; a peripheral circuit unit suitable for performing a program operation and a verification operation to the memory cell array; and a control logic suitable for controlling the peripheral circuit unit to apply a program voltage to a selected memory cell from the plurality of memory cells during the program operation, wherein the program voltage increases by a step voltage as the program operation is repeated, and wherein the step voltage gradually increases as the program operation is repeated.

### CROSS-REFERENCE TO RELATED APPLICATION

The present application claims priority to Korean patent Application No. 10-2015-0103763, filed on Jul. 22, 2015, the entire disclosure of which is herein incorporated by reference in its entirety.

### BACKGROUND

Field of Invention

Various embodiments of the present invention relate to an electronic device, and more particularly, to a semiconductor memory device and an operating method thereof.

Description of Related Art

Semiconductor memory devices can be largely classified into volatile memory devices and nonvolatile memory devices.

Nonvolatile memory devices have a relatively slow writing and reading speed, but can retain the data stored even when the power is down. Therefore, nonvolatile memory devices are used to store data that must be retained regardless of the power supply. Examples of nonvolatile memory devices include the read only memory (ROM), the mask ROM (MROM), the programmable ROM (PROM), the electrically programmable ROM (EPROM), the electrically erasable and programmable ROM (EEPROM), the flash memory, the phase-change RAM (PRAM), the magnetic RAM (MRAM), the resistive RAM (RRAM), and the ferroelectric RAM (FRAM). Furthermore, the flash memory devices may be classified into the NOR type flash memory devices and the NAND type flash memory devices.

The flash memory has the advantage of the RAM from which data or programs can be easily erased, and the advantage of the ROM from which stored data can be retained even when the power is cut off. The flash memory devices are being widely used as a storage medium for portable electronic devices such as digital cameras, personal digital assistants (PDAs) MP3 players, cellular telephones, etc.

In order to further improve the degree of Integration of a nonvolatile memory, research is actively underway to develop a multi-bit cell capable of storing a plurality of pieces of data in a single memory cell. Such a memory cell is called a multi-level cell (MLC). A single bit memory cell capable of storing a single piece of data therein is called a single level cell (SLC).

In the case of a nonvolatile memory device that uses a multi-level cell, it is important to narrow the threshold voltage distribution of a memory cell as the number of program states increases, and in order to control this, various operating options such as double verify and re-program are used when performing a program.

### SUMMARY

Various embodiments of the present invention are directed to a semiconductor memory device having an improved threshold voltage distribution of memory cells and capable of reducing an entirety of program time during a program operation.

According to an embodiment of the present disclosure, a semiconductor memory device may include a memory cell array including a plurality of memory cells; a peripheral circuit unit suitable for performing a program operation and a verification operation to the memory cell array; and a control logic suitable for controlling the peripheral circuit unit to apply a program voltage to a selected memory cell from the plurality of memory cells during the program operation, wherein the program voltage increases by a step voltage as the program operation is repeated, and wherein the step voltage gradually increases as the program operation is repeated.

According to another embodiment of the present disclosure, a semiconductor memory device may include a memory cell array including a plurality of memory cells; a peripheral circuit unit suitable for performing a program operation, pre-verification operation, and main verification operation to the memory cell array; and a control logic suitable for controlling the peripheral circuit unit: to apply a program permission voltage to a bit line of one or more memory cells among the plurality of memory cells to which the main verification operation fails, and to apply a new program voltage increased by a step voltage from a previous program voltage to the memory cells, to which the main verification operation fails, wherein a program permission voltage gradually increases by a determined voltage as the program operation is repeated, and wherein the step voltage gradually increases as the program operation is repeated.

According to another embodiment of the present disclosure, an operating method of a semiconductor memory device may include applying a program voltage to a memory cell; performing a pre-verification operation and a main verification operation to the memory cell together; when the main verification operation is determined as a failure, increasing the program voltage by a first step voltage, and increasing a potential of a bit line connected to the memory cell by a second step voltage; and repeating the applying of the program voltage, the performing of the pre-verification and main verification operations, and the increasing of the program voltage and the potential of the bit line until the main verification operation is determined as a pass, wherein the first step voltage increases as the number of times of the applying of the program voltage increases.

According to another embodiment of the present disclosure, an operating method of a semiconductor memory device may include applying a program voltage to a memory cell; performing a pre-verification operation to the memory cell; when the pre-verification operation is determined as a pass, adjusting a potential level of a bit line connected to the memory cell according to a target program state to be programmed; and performing a main verification operation to the memory cell.

### BRIEF DESCRIPTION OF THE DRAWINGS

The above and other features and advantages of the present invention will become more apparent to those of ordinary skill in the art by describing in detail embodiments with reference to the attached drawings in which:

FIG. 1 is a block diagram illustrating a semiconductor memory device according to an embodiment of the present disclosure;

FIG. 2 is a flowchart illustrating a method for operating a semiconductor memory device according to an embodiment of the present disclosure;

FIG. 3 is diagram of memory cells illustrating a method for operating a semiconductor memory device according to an embodiment of the present disclosure;

FIG. 4 is a waveform diagram illustrating a method for operating a semiconductor memory device according to an embodiment of the present disclosure;

FIG. 5 is a flowchart illustrating a method for operating a semiconductor memory device according to an embodiment of the present disclosure;

FIG. 6 is a threshold voltage distribution diagram of memory cells according to an embodiment of the present disclosure;

FIG. 7 is a block diagram illustrating a memory system that includes the semiconductor memory device of FIG. 1;

FIG. 8 is a block diagram illustrating an application example of the memory system of FIG. 7; and

FIG. 9 is a block diagram illustrating a computing system that includes a memory system explained with reference to FIG. 8.

### DETAILED DESCRIPTION

Hereinafter, embodiments will be described in greater detail with reference to the accompanying drawings. Embodiments are described herein with reference to cross-sectional illustrates that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as ‘first’ and ‘second’ may be used to describe various components, but they should not limit the various components. Those terms are only used for the purpose of differentiating a component from other components. For example, a first component may be referred to as a second component, and a second component may be referred to as a first component and so forth without departing from the spirit and scope of the present invention. Furthermore, ‘and/or’ may include any one of or a combination of the components mentioned.

Furthermore, ‘connected/accessed’ represents that one component is directly connected or accessed to another component or indirectly connected or accessed through another component.

In this specification, a singular form may include a plural form as long as it is not specifically mentioned in a sentence. Furthermore, ‘include/comprise’ or ‘including/comprising’ used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

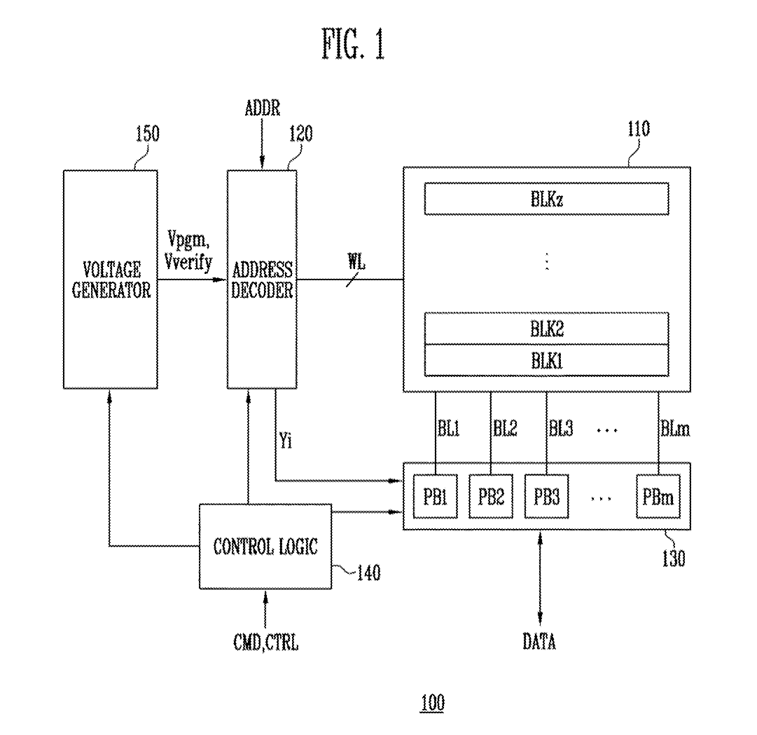

FIG. 1 is a block diagram illustrating a semiconductor memory device 100 according to an embodiment of the present disclosure.

Referring to FIG. 1, the semiconductor memory device 100 includes a memory cell array 110, address decoder 120, reading and writing circuit 130, control logic 140, and voltage generator 150.

The memory cell array 110 includes a plurality of memory blocks BLK1˜BLKz. The plurality of memory blocks BLK1˜BLKz are connected to the address decoder 120 via word lines WL. The plurality of memory blocks BLK1˜BLKz are connected to the reading and writing circuit 130 via bit lines BL1 to BLm. Each of the memory blocks BLK1˜BLKz includes a plurality of memory cells. In an embodiment, the plurality of memory cells are nonvolatile memory cells. Of the plurality of memory cells, the memory cells connected to a same word line are defined as a single page. That is, the memory cell array 110 includes of a plurality of pages.

Furthermore, each of the memory blocks BLK1˜BLKz of the memory cell array 110 includes a plurality of cell strings.

The address decoder 120, reading and writing circuit 130, and voltage generator 150 operate as peripheral circuits that drive the memory cell array 110.

The address decoder 120 is connected to the memory cell array 110 via the word lines WL. The address decoder 120 is configured to operate under the control of the control logic 140. The address decoder 120 receives an address ADDR through an input/output buffer (not illustrated) inside the semiconductor memory device 100.

The address decoder 120 decodes a line address of among s15 the provided addresses ADDR, and applies to a selected word line of a selected one among the plurality of memory blocks BLK1˜BLKz a program voltage Vpgm during program operation and a verify voltage verify during a program verification operation according to the decoded line address.

The address decoder 120 is configured to decode a row address of among the addresses ADDR provided during the program operation and the program verification operation. The address decoder 120 transmits the decoded row address (Yi) to the reading and writing circuit 130.

The program operation and the program verification operation of the semiconductor memory device 100 are performed in page units. Furthermore, the program operation and the program verification operation may be performed as a single page program operation of programming one of a plurality of pages included in a memory block or as a multi-page program operation of sequentially programming the plurality of pages.

The address ADDR provided during the program operation and the program verification operation includes a block address, a line address, and a row address. The address decoder 120 selects one memory block and one word line according to a block address and line address. The row address is decoded by the address decoder 120 and is provided to the reading and writing circuit 130.

The address decoder 120 may include a block decoder, a line decoder, a row decoder and an address buffer.

The reading and writing circuit 130 includes a plurality of page buffers PB1 to PBm. The page buffers PB1 to PBm are connected to the memory cell array 110 via the bit lines BL1 to BLm. Each of the page buffers PB1 to PBm controls a potential of corresponding bit lines BL1 to BLm according to the data DATA to be programmed when applying a program voltage during the program operation. For example, in a case where the data DATA to be programmed corresponds to a program cell, a program permission voltage is applied to the corresponding bit line, and in a case where the data DATA to be programmed corresponds to an erase cell, a program prohibition voltage is applied to the corresponding bit line. Furthermore, a potential or current of the bit lines BL1 to BLm is sensed and the program verification operation is performed during the program operation. When it is determined based on a result of the verification operation that a threshold voltage of the memory cell has increased above a target threshold voltage, a program prohibition voltage of the corresponding bit line is applied.

Furthermore, as the number of times of applying the program voltage increases during the program operation, each of the plurality of page buffers PB1 to PBm may gradually increase a program permission voltage to be applied to the bit line. Herein, when a first program permission voltage is defined as Vb1, a second program permission voltage may be defined as Vb1+a, a third program permission voltage may be defined as Vb1+b, and a fourth program permission voltage may be defined as Vb1+c, where b is greater than a, and c is greater than b.

The reading and writing circuit 130 operates under the control of the control logic 140.

In an embodiment, the reading and writing circuit 130 may include page buffers (or page registers), row selecting circuit and the like.

The control logic 140 is connected to the address decoder 120, reading and writing circuit 130, and voltage generator 150. The control logic 140 receives a command CMD and control signal CTRL through an input/output buffer (not illustrated) of the semiconductor memory device 100. The control logic 140 is configured to control the overall operations of the semiconductor memory device 100 in response to the command CMD and control signal CTRL. The control logic 140 controls the voltage generator 150 to gradually increase the program voltage such that a step voltage of the program voltage increases gradually as the number of times of applying the program voltage during the program operation increases. Furthermore, the control logic 140 controls the reading and writing circuit 130 such that a program permission voltage applied to a bit line increases gradually as the number of times of applying a program voltage increases. Herein, the program voltage Vpgm increases by as much as the step voltage value than a previous program voltage, and the step voltage value gradually increases to Vstep, Vstep+a, Vstep+b, and Vstep+c, where b is greater than a, and c is greater than b. Herein, voltages a, b, and c are the same as the increment amount a, b, and c of the program permission voltage, respectively. That is, it is desirable that the step voltage value is increased by as much as the increment amount of the program permission voltage.

Furthermore, the control logic 140 controls the address decoder 120, reading and writing circuit 130, and voltage generator 150 to perform a pre-verification operation using a pre-verify voltage that is less than the target threshold voltage value and to perform a main verification operation using a main verify voltage that is the same as the target threshold voltage value.

The voltage generator 150 generates the program voltage Vpgm and the verify voltage verify during the program operation and the program verification operation, respectively, under the control of the control logic 140. The voltage generator 150 generates the program voltage Vpgm that increases by as much as the step voltage value as the number of times of applying the program voltage increases, and the step voltage value gradually increases as the number of times of applying the program voltage increases.

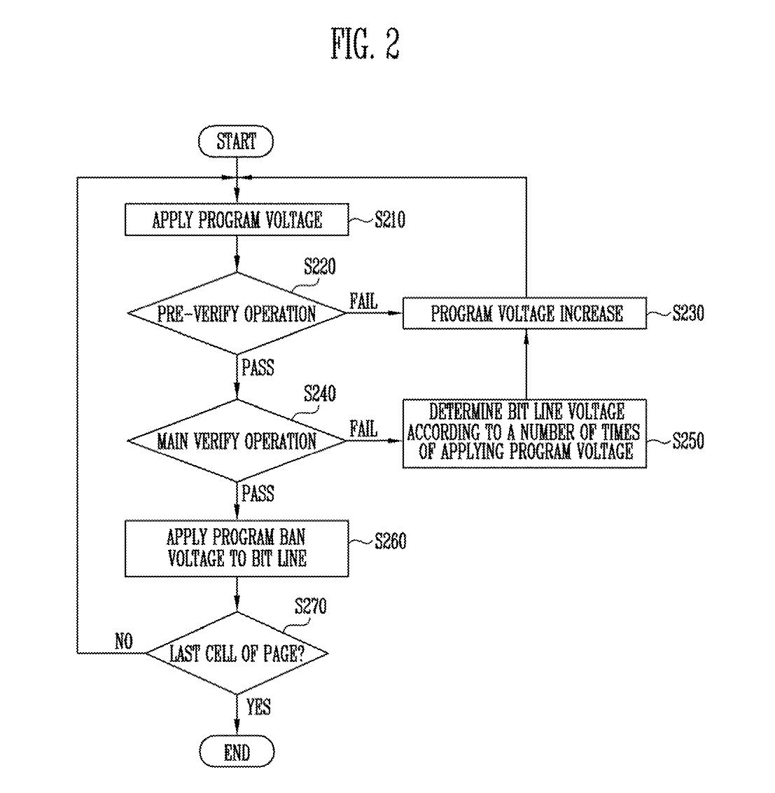

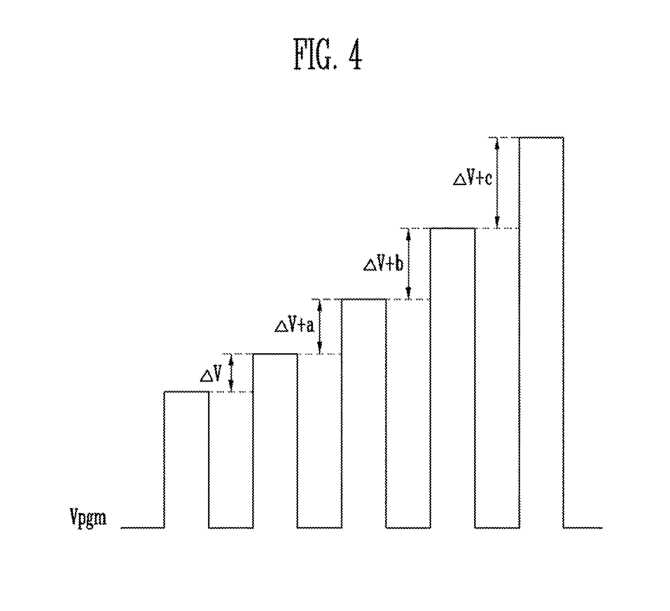

Hereinafter, explanation will be made on a method for operating a semiconductor memory device according to an embodiment of the present disclosure with reference to FIGS. 1 to 4.

An embodiment of the present disclosure will be explained by way of an example of programming memory cells to erase state Er and a multiple program state PV1 to PV7.

Program Voltage Application at Step S210

The reading and writing circuit 130 temporarily stores data DATA to be programmed, and controls potential levels of bit lines BL1 to BLm to program permission voltage or program prohibition voltage according to the stored data.

The voltage generator 150 generates the program voltage Vpgm to be applied to a selected word line and a pass voltage to be applied to unselected word lines.

The address decoder 120 selects one word line for performing the single page program operation according to the address signal ADDR, and applies the program voltage Vpgm generated in the voltage generator 150. Herein, to the remaining unselected word lines, the pass voltage is applied.

Pre-Verification Operation at Step S220

After the application of the program voltage of step S210, a pre-verification operation is performed at step S220. The pre-verification operation is performed using pre-verify voltages PV1_pre to PV7_pre that are less than the target threshold voltage.

The voltage generator 150 sequentially generates the pre-verify voltages PV1_pre to PV7_pre to be applied to the selected word line according to the address signal ADDR, and the address decoder 120 sequentially applies the pre-verify voltages PV1_pre to PV7_pre to the selected word line. Herein, the reading and writing circuit 130 senses potential levels of the bits lines BL1 to BLm and performs the pre-verification operation when the pre-verify voltages PV1_pre to PV7_pre are applied.

To memory cells determined as pass as a result of the pre-verification operation, the threshold voltage distribution may be improved by increasing the program permission voltage applied to the bit line during a subsequent operation of applying the program voltage. Herein, when a first program permission voltage is defined as Vb1, a second program permission voltage may be defined as Vb1+a, a third program permission voltage may be defined as Vb1+b, and a fourth program permission voltage may be defined as Vb1+c, where b is greater than a, and c is greater than b.

Program Voltage Increase at Step S230

When it is determined as a result of the aforementioned pre-verification operation of step S220 that the threshold voltage of the memory cell selected is less than the pre-verify voltage PV1_pre to PV7_pre and thus determined as a failure, the program voltage Vpgm used in the previous application of the program voltage of step S210 is increased so as to set an increased program voltage Vpgm.

Herein, the increased program voltage may desirably be set such that the step voltage value becomes greater as the number of times of applying the program voltage increases. For example, a second program voltage is increased by a first step voltage (ΔV) from a first program voltage, and a third program voltage is increased by a second step voltage (αV+a) from the second program voltage, and a fourth program voltage Is increased by a third step voltage (ΔV+b) from the third program voltage, and a fifth program voltage is increased by a fourth step voltage (ΔV+c) from the fourth program voltage, where a is less than b, and b is less than c (a<b<c). That is, the step voltage value of the program voltage becomes gradually greater as the number of times of applying a program voltage increases. Furthermore, voltage increments a, b, and c are the same as the increments of the program permission voltage. That is, it is desirable that the step voltage value is increased by as much as the increment of the program permission voltage.

Main Verification Operation at Step S240

When it is determined as a result of the aforementioned pre-verification operation of step S220 that the threshold voltage of the selected memory cell is the same or greater than the pre-verify voltage PV1_pre to PV7_pre and thus determined as a pass, a main verification operation is performed at step S240.

The main verification operation is performed using the main verify voltages PV1_main to PV7_main that is the same as the target threshold voltage.

The voltage generator 150 sequentially generates the main verify voltage PV1_main to PV7_main to be applied to the selected word line, and the address decoder 120 sequentially applies the main verify voltages PV1_main to PV7_main to the selected word line according to the address signal ADDR. Herein, the reading and writing circuit 130 senses a potential level of the bit lines BL1 to BLm and performs the main verification operation when the main verify voltage PV1_main to PV7_main are being applied.

In an embodiment, a potential level of a main verify voltage of an N^{th} program state PVN is the same as a potential level of a pre-verify voltage of an N+1^{th} program state PVN+1. Therefore, the main verification operation of the N^{th} program state PVN and the pre-verification operation of the N+1^{th} program state PVN+1 may proceed at the same time. For example, the main verification operation to a first program state PV1 and the pre-verification operation to a second program state PV2 may be performed at the same time, thereby reducing the overall program time.

Bit Line Voltage According to the Application Number of Times of the Program Voltage at Step S250

When it is determined as a result of the main verification operation of step S240 that the threshold voltage of the selected memory cell is less than the main verify voltage PV1_main to PV7_main and thus is determined as a failure, the bit line voltage is set according to the number of times of applying the program voltage.

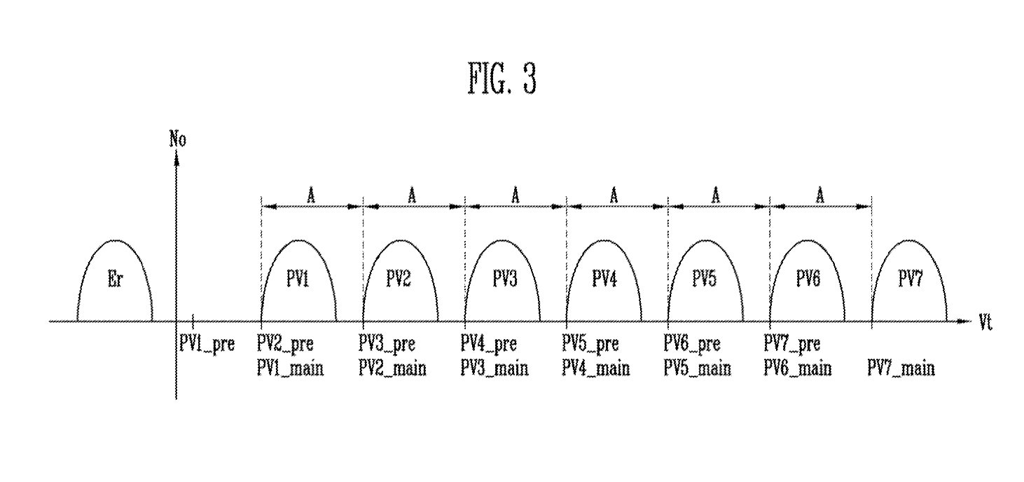

In an embodiment of the present disclosure, the program voltage Vpgm increases by the step voltage value, which gradually increases as the number of times of applying the program voltage increases. Due to this, the higher the threshold voltage value, the wider the threshold voltage distribution width of the plurality of program states PV1 to PV7. In a case where the widths of the threshold voltage distribution of the plurality of program states PV1 to PV7 are different from one another, the main verify voltage of the N^{th} program state and the pre-verify voltage of the N+1^{th} program state will not be the same, and thus it will not be possible to perform the pre-verification operation and the main verification operation at the same time as in the embodiment of the present disclosure. Therefore, in order to maintain the threshold voltage distribution width (shown as “A” in FIG. 3) of the plurality of program states PV1 to PV7 at a certain level during the program operation, a potential level of the program permission voltage being applied to the bit lines BL1 to BLm is increased as the number of times of applying the program voltage increases. Due to this, even when the program voltage increases by a large extent, the increased threshold voltage value of the memory cell will be retained at a certain level, thereby controlling the threshold voltage width (shown as “A” in FIG. 3) according the program state of the memory cells at a certain level.

Program Prohibition Voltage Application to Bit Line at Step S260

In a case where it is determined as a result of the aforementioned main verification operation of step S240 that the threshold voltage of the memory cell selected is the same or greater than the main verify voltage PV1_main to PV7_main and thus is determined as a pass, a program prohibition voltage is applied to the bit line connected to the selected memory cell, thereby preventing the threshold voltage of the selected memory cell from increasing.

Determination of Page Address at Step S270

When it is determined that the main verification operation of all memory cells of the selected page is a pass, a check is made whether or not the selected page is a last page, and when there is a next page, steps S210 to S270 are repeated to the last page.

The aforementioned steps S210 to S260 are sequentially repeated with the pre-verify voltage and the main verify voltage being changed for each program state illustrated in FIG. 3.

In an embodiment as the number of times of applying a program voltage increases, the size of the step voltage value of the program voltage being applied to the cell increases, and the program permission voltage being applied to the bit line connected to the selected memory cell gradually increases as well.

When the number of times of applying the program voltage increases once, the size of the step voltage value may be increased and the program permission voltage may be increased. Furthermore, when the number of times of applying the program voltage increases to a predetermined number of times or more, the size of the step voltage value may be increased once and the program permission voltage may be increased once. For example, when the number of times of applying a program voltage increases twice, the size of the step voltage value may be increased once and the program permission voltage may be increased once, thereby preventing excessive increase in the size of the step voltage value and the program permission voltage.

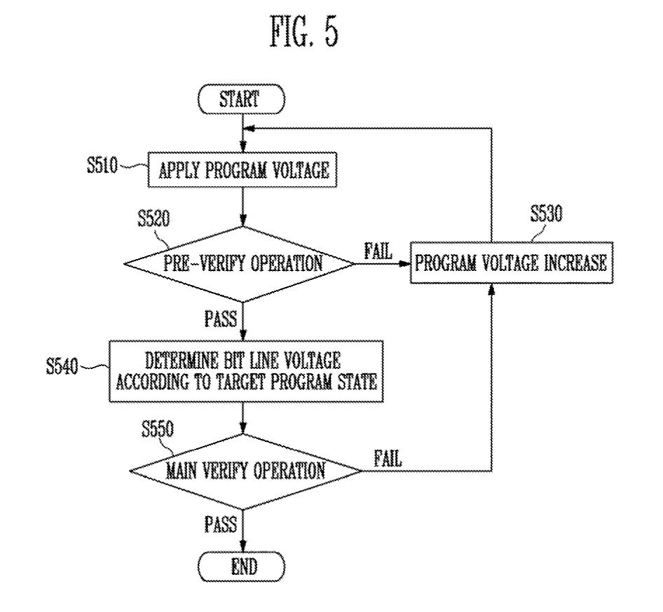

Hereinafter, a method for operating a semiconductor memory device according to an embodiment of the present disclosure will be described with reference to FIGS. 1, 5, and 6.

Program Voltage Application at Step S510

The reading and writing circuit 130 temporarily stores data DATA to be programmed, and controls potential levels of bit lines BL1 to BLm to the program permission voltage or program prohibition voltage according to the stored data.

The voltage generator 150 generates the program voltage Vpgm to be applied to the selected word line and a pass voltage to be applied to the unselected word lines.

The address decoder 120 selects one word line for performing the single page program operation according to the address signal ADDR, and applies the program voltage Vpgm generated in the voltage generator 150. Herein, the pass voltage is applied to the unselected remaining word lines.

Pre-Verification Operation at Step S520

After the application of the program voltage of step S510, a pre-verification operation is performed at step S520. The pre-verification operation is performed using pre-verify voltages PV1_pre to PV7_pre that are less than the target threshold voltage.

The voltage generator 150 sequentially generates pre-verify voltages PV1_pre to PV7_pre to be applied to the selected word lines according to the address signal ADDR, and the address decoder 120 sequentially applies the pre-verify voltages PV1_pre to PV7_pre to the selected word lines. Herein, the reading and writing circuit 130 senses potential levels of the bit lines BL1 to BLm and performs the pre-verification operation when the pre-verify voltage (PV1_pre˜PV7-pre) are being applied.

Program Voltage Increase at Step S530

When it is determined as a result of the pre-verification operation of step S520 that the threshold voltage of the selected memory cell is less than the pre-verify voltage PV1_pre to PV7_pre and thus determined as a failure, the program voltage Vpgm used at the previous application of the program voltage of step S510 is increased so as to set an increased program voltage Vpgm.

Bit Line Voltage According to Target Program State at Step S540

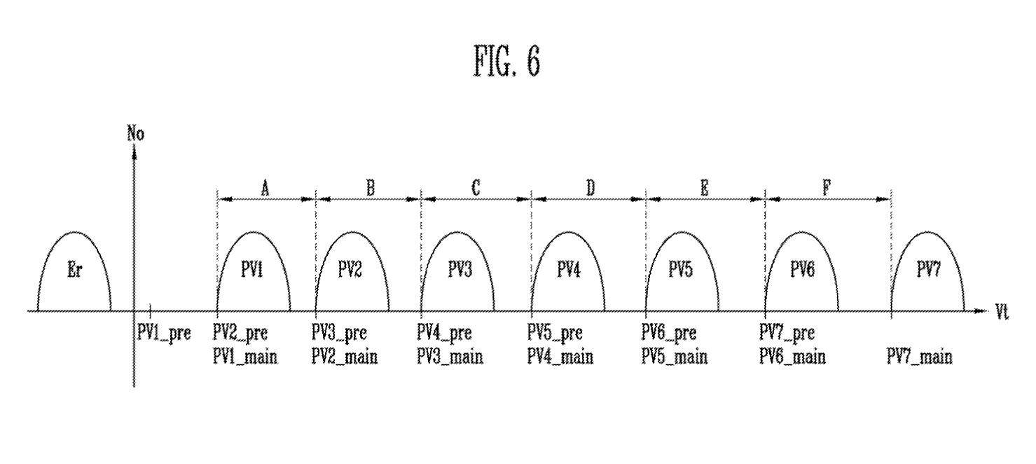

When it is determined as a result of the aforementioned pre-verification operation of step S520 that the threshold voltage of the selected memory cell is higher than the pre-verify voltage PV1_pre to PV7_pre and thus determined as a failure, the voltage being applied to the bit lines BL1 to BLm connected to each memory cell is adjusted. More specifically, the bit lines BL1 to BLm are precharged during the main verification operation after the pre-verification operation such that the higher voltage is applied to the bit line corresponding to the memory cell of the higher target program state. For example, it is set such that the voltage being applied to a bit line of the memory cell to be programmed to a second state (shown as “PV2” in FIG. 6) is higher than the voltage being applied to a bit line of the memory cell to be programmed to a first state (shown as “PV1” in FIG. 6). Furthermore, it is set such that the voltage being applied to a bit line of the memory cell to be programmed to a third state (shown as “PV3” in FIG. 6) is higher than the voltage being applied to a bit line of the memory cell being programmed to the second state (shown as “PV2” in FIG. 6). As aforementioned, it is set such that the higher voltage is applied to the bit line corresponding to the memory cell of the higher target program state. This is to compensate, by adjusting the bit line voltage, for the difference becoming greater between the pre-verify voltage and main verify voltage as the voltage distribution of the target program state becomes higher.

An embodiment of the present disclosure was explained by way of an example of adjusting the bit line voltage according to each target program state, but it is also possible to group adjacent target program states, and adjust a single bit line voltage for each group.

Main Verification Operation at Step S550

After the determination of the bit line voltage of step S540, the main verification operation is performed at step S550.

The main verification operation is performed using the main verify voltage PV1_main to PV7_main that is the same as the target threshold voltage.

The voltage generator 150 sequentially generates main verify voltages PV1_main to PV7_main to be applied to a selected word line, and the address decoder 120 sequentially applies the main verify voltages PV1_main to PV7_main to the selected word line according to the address signal ADDR. Herein, the reading and writing circuit 130 senses a potential level of bit lines BL1 to BLm and performs a main verification operation when the main verify voltages PV1_main to PV7_main are being applied.

The aforementioned steps S510 to S550 are sequentially repeated by alternating the pre-verify voltage and main verify voltage for each of the program state PV1 to PV7 Illustrated in FIG. 6.

In an embodiment of the present disclosure, a potential level of the main verify voltage of the N^{th} program state PVN is the same as a potential level of a pre-verify voltage of the N+1^{th} program state PVN+1. Therefore, it is possible to proceed with the main verification operation of the N^{th} program state PVN and the pre-verification operation of the N+1^{th} program state PVN+1 at the same time. For example, it is possible to perform the main verification operation of the first program state PV1 and the pre-verification operation of the second program state PV2 at the same time, thereby reducing the overall program time.

In an embodiment of the present disclosure, it is possible to adjust a potential level of a bit line differently according to the target program state prior to performing the main verification operation after the pre-verification operation, thereby improving the threshold voltage distribution of the memory cells.

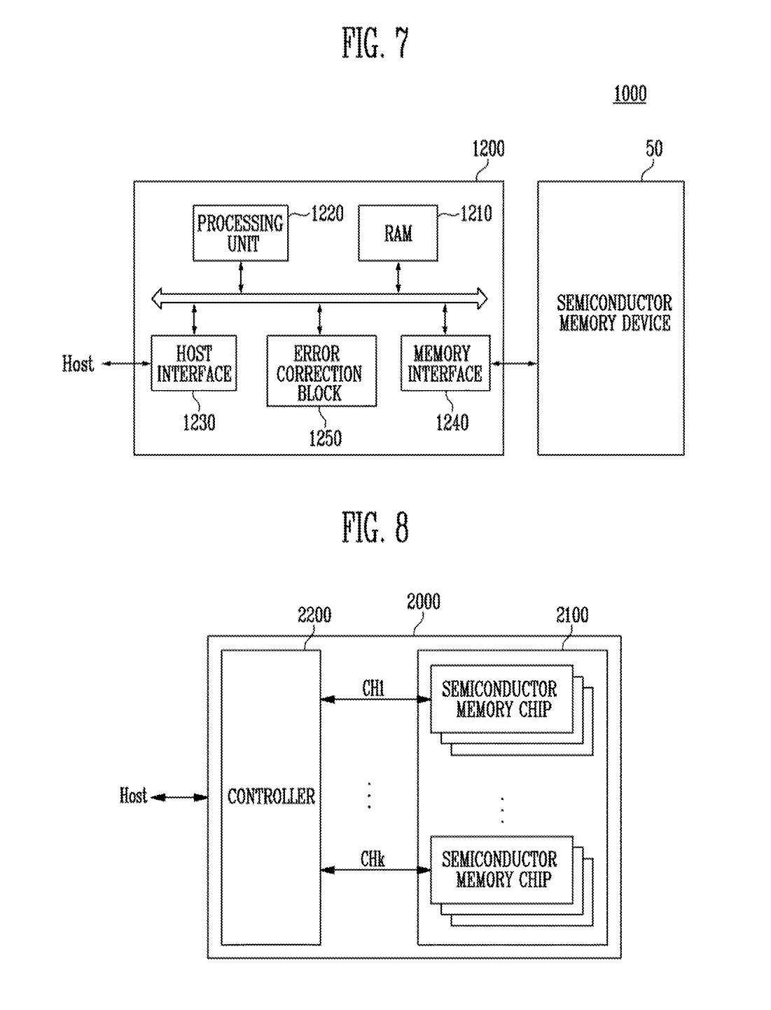

FIG. 7 is a block diagram Illustrating a memory system that includes a semiconductor memory device of FIG. 1.

Referring to FIG. 7, the memory system 1000 includes a semiconductor memory device 50 and a controller 1200.

The semiconductor memory device 50 is the same as the semiconductor memory device explained with reference to FIG. 1, and thus repeated explanation will be omitted.

The controller 1200 is connected to a host and semiconductor memory device 50. The controller 1200 is configured to access the semiconductor memory device 50 in response to a request from the host. For example, the controller 1200 is configured to control operations of reading, writing, erasing, and background operations of the semiconductor memory device 50. The controller 1200 is configured to provide an Interface between the semiconductor memory device 50 and host. The controller 1200 is configured to drive a firmware for controlling the semiconductor memory device 50.

The controller 1200 includes a RAM (Random Access Memory) 1210, processing unit 1220, host interface 1230, memory interface 1240, and error correction block 1250. The RAM 1210 is used as at least one of an operating memory of the processing unit 1220, a cache memory between the semiconductor memory device 50 and host, and a buffer memory between the semiconductor memory device 50 and host. The processing unit 1220 controls the overall operations of the controller 1200. Furthermore, the controller 1200 may temporarily store program data being provided from the host during a writing operation.

The host interface 1230 includes a protocol for performing data exchange between the host and the controller 1200. In an embodiment, the controller 1200 is configured to communicate with the host through at least one of various interface protocols such as a USB (Universal Serial Bus) protocol, MMC (Multimedia Card) protocol, PCI (Peripheral Component Interconnection) protocol, PCI-E (PCI-Express) protocol, ATA (Advanced Technology Attachment) protocol, Serial-ATA protocol, Parallel-ATA protocol, SCSI (Small Computer Small Interface) protocol, ESDI (Enhanced Small Disk Interface) protocol, and IDE (Integrated Drive Electronics) protocol, and/or private protocol.

The memory Interface 1240 interfaces with the semiconductor memory device 50. For example, the memory interface includes a NAND interface or NOR interface.

The error correction block 1250 is configured to detect and correct an error of data provided from the semiconductor memory device 50 using an ECC (Error Correcting Code). The processing unit 1220 adjusts a reading voltage according to a result of error detection of the error correction block 1250, and controls the semiconductor memory device 50 to perform a re-reading. In an embodiment, the error correction block 1250 may be provided as a component of the controller 1200.

The controller 1200 and semiconductor memory device 50 may be integrated in one semiconductor device. In an embodiment, the controller 1200 and semiconductor memory device 50 are integrated into one semiconductor device, and form a memory card. For example, the controller 1200 and semiconductor memory device 50 are integrated into one semiconductor device, and form a memory card such as a PC card (PCMCIA, personal computer memory card international association), compact flash card (CF), smart media card (SM, SMC), memory stick, multimedia card (MMC, RS-MMC, MMCmicro), SD card (SD, miniSD, microSD, SDHC), and/or universal flash memory apparatus (UGS).

The controller 1200 and semiconductor memory device 50 may be Integrated into one semiconductor device, and form an SSD (solid state drive). The SSD includes a storage device configured to store data in a semiconductor memory. In a case where the memory system 1000 is being used as an SSD, an operating speed of the host connected to the memory system 1000 is significantly improved.

In another example, the memory system 1000 is provided as one of various components of an electronic device such as a computer, UMPC (Ultra Mobile PC), workstation, net-book, PDA (Personal Digital Assistants), portable computer, web tablet, wireless phone, mobile phone, smart phone, e-book, PMP (portable multimedia player), portable game device, navigation device, black box, digital camera, 3-dimensional television, digital audio recorder, digital audio player, digital picture recorder, digital picture player, digital video recorder, digital video player, device configured to transceive information in a wireless environment, one of various electronic devices that form a home network, one of various electronic devices that form a computer network, one of various electronic devices that form a telematics network, RFID device, and/or computing system.

In an embodiment, the semiconductor memory device 50 or memory system 1000 may be packaged in various formats. For example, the semiconductor memory device 50 or memory system 1000 may be packaged in a method such as a PoP (Package on Package), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi-Chip Package (MCP), Wafer-level Fabricated Package (WFP), Wafer-Level Processed Stack Package (WSP), and be mounted.

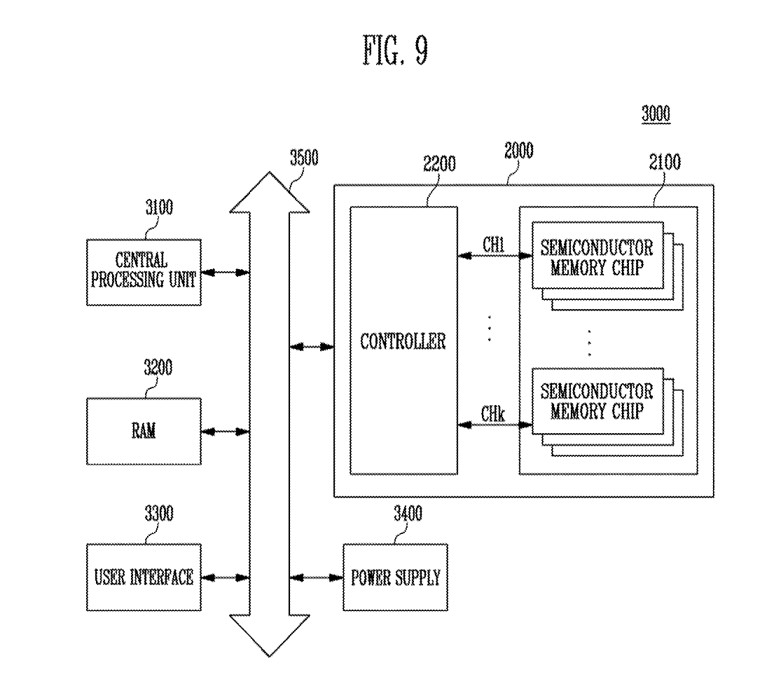

FIG. 8 is a block diagram Illustrating an application example of the memory system of FIG. 7.

Referring to FIG. 8, the memory system 2000 includes a semiconductor memory device 2100 and controller 2200. The semiconductor memory device 2100 includes a plurality of semiconductor memory chips. The plurality of semiconductor memory chips are divided into a plurality of groups.

In FIG. 8, it is illustrated that each of the plurality of groups communicate with the controller 2200 through a first to k^{th} channels (CH1˜CHk). Each of the semiconductor memory chip will be configured in the same manner as the semiconductor memory device 100 explained with reference to FIG. 1, and operate accordingly.

Each group is configured to communicate with the controller 2200 through one common channel. The controller 2200 is configured in the same manner as the controller 1200 explained with reference to FIG. 7, and is configured to control the plurality of memory chips of the semiconductor memory device 2100 through the plurality of channels (CH1˜CHk).

FIG. 9 is a block diagram illustrating a computing system that includes the memory system explained with reference to FIG. 8.

Referring to FIG. 9, the computing system 3000 includes a central processing unit 3100, RAM (Random Access Memory) 3200, user terminal 3300, power source 3400, system bus 3500, and memory system 2000.

The memory system 2000 is electrically connected to the central processing unit 3100, RAM 3200, user interface 3300, and power source 3400 through a system bus 3500. The data provided through the user interface 3300 or processed through the central processing unit 3100 is stored in the memory system 2000.

In FIG. 9, it is Illustrated that the semiconductor memory device 2100 is connected to the system bus 3500 through the controller 2200. However, the semiconductor memory device 2100 may be configured to be directly connected to the system bus 3500. Herein, the functions of the controller 2200 may be performed by the central processing unit 3100 and RAM 3200.

FIG. 9 illustrates that the memory system 2000 explained with reference to FIG. 8 is provided. However, the memory system 2000 may be substituted with the memory system 1000 explained with reference to FIG. 7. In an embodiment, the computing system 3000 may be configured to include all the memory systems 1000, 2000 explained with reference to FIGS. 8 and 7.

According to the aforementioned embodiments of the present disclosure, it is possible to adjust a size of a step voltage value of a program voltage being applied to a selected memory cell as the number of times of applying a program voltage increases, and to gradually increase a potential level of a bit line connected to the selected memory cell, thereby reducing the program operation time and improving the threshold voltage distribution of the memory cells.

In the drawings and specification, there have been disclosed typical exemplary embodiments of the invention, and although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A semiconductor memory device comprising:
a memory cell array including a plurality of memory cells;
a peripheral circuit unit suitable for performing a program operation and a verification operation to the memory cell array; and
a control logic suitable for controlling the peripheral circuit unit to apply a program voltage to a selected memory cell from the plurality of memory cells during the program operation,
wherein the program voltage increases by a step voltage as the program operation is repeated, and
wherein the step voltage gradually increases as the program operation is repeated.

2. The device according to claim 1, wherein the control logic controls the peripheral circuit unit to perform a pre-verification operation during the verification operation after the program operation.

3. The device according to claim 2, wherein the control logic controls the peripheral circuit unit to perform the pre-verification operation using a pre-verify voltage that is less than a target threshold voltage of the selected memory cell.

4. The device according to claim 2, wherein, when the pre-verification operation is determined as a failure, the control logic controls the peripheral circuit unit to repeat the program operation with the program voltage increased by the step voltage.

5. The device according to claim 3, wherein, when the pre-verification operation is determined as a pass, the control logic controls the peripheral circuit unit to perform a main verification operation using a main verify voltage that is the same as the target threshold voltage.

6. The device according to claim 5, wherein the main verify voltage of the main verification operation to an N^{th} program state and the pre-verify voltage of the pre-verification operation to an N+1^{th} program state are the same.

7. The device according to claim 6, wherein the main verification operation to the N^{th} program state and the pre-verification operation to the N+1^{th} program state are performed simultaneously.

8. The device according to claim 6, wherein a threshold voltage distribution width of the N^{th} program state and a threshold voltage distribution width of the N+1^{th} program state are the same.

9. The device according to claim 5,
wherein the control logic controls the peripheral circuit unit to apply a program permission voltage to a bit line connected to one or more memory cells, to which the main verification operation fails, of among the plurality of memory cells, and
wherein the program permission voltage gradually Increases as the program operation is repeated.

10. The device according to claim 9,
wherein the program permission voltage Increases by a determined voltage as the program operation is repeated, and
wherein the determined voltage gradually increases as the program operation is repeated.

11. The device according to claim 10,
wherein the determined voltage and the step voltage gradually increase as the program operation is repeated, and
wherein increments of the determined voltage and the step voltage are the same as each other.

12. A semiconductor memory device comprising:
a memory cell array including a plurality of memory cells;
a peripheral circuit unit suitable for performing a program operation, pre-verification operation, and main verification operation to the memory cell array; and
a control logic suitable for controlling the peripheral circuit unit:
to apply a program permission voltage to a bit line of one or more memory cells among the plurality of memory cells to which the main verification operation fails, and
to apply a new program voltage increased by a step voltage from a previous program voltage to the memory cells, to which the main verification operation fails,
wherein a program permission voltage gradually increases by a determined voltage as the program operation is repeated, and
wherein the step voltage gradually increases as the program operation is repeated.

13. The device according to claim 12, wherein the control logic controls the peripheral circuit unit to perform the pre-verification operation using a pre-verify voltage that is lower than a target threshold voltage of a selected memory cell.

14. The device according to claim 12, wherein, when the pre-verification operation is determined as a failure, the control logic controls the peripheral circuit unit to repeat the program operation with the new program voltage increased by the step voltage.

15. The device according to claim 13, wherein, when the pre-verification operation is determined as a pass, the control logic controls the peripheral circuit unit to perform the main verification operation using a main verify voltage that is the same as the target threshold voltage.

16. The device according to claim 15, wherein the main verify voltage of the main verification operation to an N^{th} program state, and the pre-verify voltage of the pre-verification operation to an N+1^{th} program state are the same.

17. The device according to claim 16, wherein the main verification operation to the N^{th} program state and the pre-verification operation to the N+1^{th} program state are performed simultaneously.

18. The device according to claim 12, wherein increments of the determined voltage and the step voltage are the same as each other.
